(19) United States
(12) Patent Application Publication
(10) Pub. No.: US 2019/0372542 A1
(43) Pub. Date: Dec. 5, 2019

(54) NOISE FILTER

(71) Applicant: Mitsubishi Electric Corporation, Tokyo (JP)

(72) Inventors: Akihito KOBAYASHI, Tokyo (JP); Naoto OKA, Tokyo (JP); Hideyuki OHASHI, Tokyo (JP); Yasuhiro SEKIMOTO, Tokyo (JP)

(73) Assignee: Mitsubishi Electric Corporation, Tokyo (JP)

(21) Appl. No.: 16/473,298

(22) PCT Filed: Feb. 6, 2017
(86) PCT No.: PCT/JP2017/004198

§ 371 Date: Jun. 25, 2019

(51) Int. Cl. H03H 1/02; H05K 1/02; H05K 1/16; H03H 7/06; H05K 1/18

(52) U.S. Cl. CPC H03H 1/02; H05K 1/0216; H05K 1/162; H03H 7/06; H05K 2201/10022; H05K 1/181; H05K 2201/093; H05K 2201/10015; H05K 1/167

(57) ABSTRACT

A sub wiring pattern (21) branches from a first branching portion (20a) of a main wiring pattern (20), and connects to the main wiring pattern (20) at a second branching portion (20b). In a portion of the main wiring pattern (20) from the first branching portion (20a) to the second branching portion (20b), a resistor element (12) and a three-terminal capacitor element (13) are serially connected. The sub wiring pattern (21) is formed so that its path length is larger than a length of a path from the first branching portion (20a) to the second branching portion (20b) in the main wiring pattern (20).

### TECHNICAL FIELD

The present invention relates to a noise filter for removing high-frequency electromagnetic noise that leaks due to anti-resonance caused by a parasitic component in a printed-circuit board.

### BACKGROUND ART

On a printed-circuit board, various circuit elements, such as a semiconductor integrated element and the like, can be implemented. Further, on the printed-circuit board, in many cases, a bypass capacitor is implemented as a noise filter for removing high-frequency electromagnetic noise generated in the printed-circuit board. For example, for reducing power supply noise in the printed-circuit board, it is required to reduce impedance of the power supply. For that reason, a noise filter using a bypass capacitor is implemented between a power terminal and a circuit element on the printed-circuit board.

Recently, there are increasing cases where a three-terminal capacitor is employed as the bypass capacitor. It is said that the three-terminal capacitor is higher in noise suppression performance than a conventionally used two-terminal capacitor, and is implemented by dividing a pattern for power supply that is formed on the printed-circuit board and that connects the circuit element with a power supply circuit for power feeding, namely, it is implemented penetratingly through the pattern.

However, when the three-terminal capacitor is implemented penetratingly, the following two problems arise.

The first problem is that LC parallel resonance (anti-resonance) is caused at a specific frequency, by parasitic inductances of the three-terminal capacitor and the wiring and via for implementation and by a parasitic capacitance between the pattern for power supply and a ground pattern formed on the printed-circuit board. In a frequency range where anti-resonance occurs, noise-current charging and discharging are repeated between the parasitic inductances and the parasitic capacitance, so that the bypass capacitor does not function and thus the noise reduction effect is impaired. Accordingly, in order to improve the performance of the noise filter, it is required to reduce noise current in the frequency range where anti-resonance occurs.

The second problem is that, in the penetrating implementation of the three-terminal capacitor, when stress is applied to the three-terminal capacitor because of deformation of the board or the like, to thereby develop a crack, it becomes unable to supply power to circuit elements. Thus, the product durability is degraded.

With respect to the reduction of noise current regarding the first problem, as shown in Patent Document 1, for example, there is a configuration in which a CR snubber circuit that includes a capacitor and a resistor serially connected to each other is arranged between the power terminal of the circuit element and the ground terminal. By inserting the resistor in a current bypass path passing via the capacitor, the resistor consumes noise current, and consequently, the performance of the noise filter in the frequency range where anti-resonance occurs can be improved.

Further, with respect to the degradation in product durability in the second problem, there is such implementation in which the pattern for power supply that is formed on the printed-circuit board and that connects the circuit element with the power supply circuit for power feeding is not divided (non-penetrating implementation).

### CITATION LIST

### Patent Document

Patent Document 1: Japanese Patent No. 5558645

### SUMMARY OF THE INVENTION

### Problems to be Solved by the Invention

However, in the technique described in Patent Document 1, although it is possible to consume noise current by the resistor to thereby improve the performance of the noise filter in the frequency range where anti-resonance occurs, there is a problem that, in the other frequency range, the performance of the noise filter deteriorates due to the resistance value of the resistor inserted in the current bypass path and due to the parasitic inductances of the resistor and its connection wiring. In particular, in order to effectively use the performance of the noise filter using a three-terminal capacitor, it is essential to reduce the parasitic inductance inserted in the bypass path. In this respect, such a measure can be considered in which, in order to magnetically cancel out the parasitic inductance of the wiring, the component parts are arranged so that a current flowing through the resistor and a current flowing through the capacitor are directed inversely. However, in this method, it is unable to fully cancel out the inductance and thus to reduce the resistance value.

Further, in the non-penetrating implementation as a solution for the second problem, because the pattern for power supply that connects a circuit element with the power supply circuit for power feeding is not divided, there is such a path in which noise flows out from the circuit element to the power feeding point without passing the three-terminal capacitor. Thus, there is a problem that the performance of the noise filter deteriorates in a frequency range where the inductance becomes dominant.

This invention has been made to solve the above problems, and an object thereof is to provide a noise filter which can, while reducing noise current in the frequency range where anti-resonance occurs, prevent its performance from deteriorating in the other frequency range, and which can increase durability.

### Means for Solving the Problems

A noise filter according to the invention includes: a main current path part arranged between a power element and a circuit element; a sub current path part that braches from a first branching point placed at one end of the main current path part and that connects to the main current path part at a second branching point placed at another end of the main current path part; a three-terminal capacitor element having a pair of electrode terminals and a ground terminal arranged between the pair of electrode terminals, in which the pair of electrode terminals are connected serially in a path from the first branching point to the second branching point, and the ground terminal is connected to a ground conductor; and a resistor element having a pair of electrode terminals which are connected serially in the path from the first branching point to the second branching point. A path length of the sub current path part is larger than a length of the path from the first branching point to the second branching point in the main current path part.

### Effect of the Invention

In the noise filter according to this invention, the path length of the sub current path part is set to be larger than the length of the path from the first branching point to the second branching point in the main current path part. This makes it possible, while reducing noise current in the frequency range where anti-resonance occurs, to prevent the performance from deteriorating in the other frequency range, and to increase the durability.

### BRIEF DESCRIPTION OF THE DRAWINGS

FIG. 1 is an illustration diagram of a layered structure of a printed-circuit board for implementing a noise filter according to Embodiment 1 of the invention;

FIG. 2 is a configuration diagram showing the noise filter according to Embodiment 1 of the invention;

FIG. 3 is an illustration diagram showing a current path of noise current in the noise filter according to Embodiment 1 of the invention;

FIG. 4 is an illustration diagram of a layered structure of a printed-circuit board for implementing a noise filter according to Embodiment 2 of the invention; and

FIG. 5 is a perspective view showing a configuration of the noise filter according to Embodiment 2 of the invention.

### MODES FOR CARRYING OUT THE INVENTION

Hereinafter, for illustrating the present invention in more detail, some embodiments for carrying out the invention will be described with reference to the accompanying drawings.

### Embodiment 1

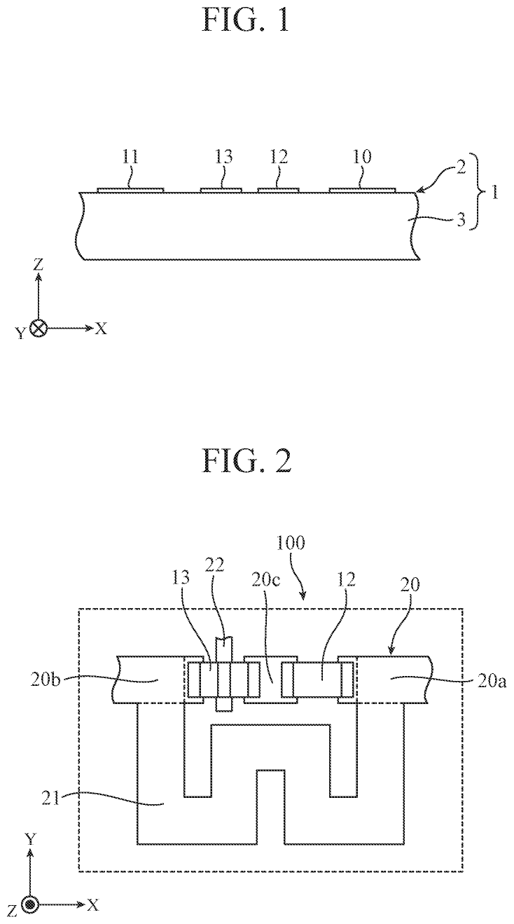

FIG. 1 is an illustration diagram of a layered structure of a printed-circuit board 1 for implementing a noise filter according to this embodiment of the invention. The illustrated printed-circuit board 1 has the layered structure in which a first wiring layer 2 is stacked in a thickness direction Z of an insulating layer 3. The printed-circuit board 1 is a single-sided board. The first wiring layer 2 is distributed on an X-Y plane perpendicular to the thickness direction Z. Further, on the surface of the printed-circuit board 1, an electronic component 10 such as an LSI or IC as a circuit element, a power element 11, a resistor element 12 and a three-terminal capacitor element 13 are implemented. The insulating layer 3 is formed by an electrical insulation resin material such as, for example, an epoxy resin, a polyimide resin or the like.

FIG. 2 is a configuration diagram of a noise filter 100 according to Embodiment 1. The illustrated noise filter 100 includes: a main wiring pattern 20; a sub wiring pattern 21 that branches from a first branching portion 20a placed on one end side of the main wiring pattern 20 and that connects to a second branching portion 20b placed on another end side of the main wiring pattern 20; a ground conductor 22; the resistor element 12; and the three-terminal capacitor element 13. The main wiring pattern 20, the sub wiring pattern 21 and the ground conductor 22 are formed on a surface layer of the insulating layer 3 as a group of configuration elements of the first wiring layer 2. Further, the first wiring layer 2 is formed by an electrical conductor such as a copper foil or the like.

The main wiring pattern 20 and the sub wiring pattern 21 are conductor patterns for power feeding that make a connection between the electronic component 10 and the power element 11. The path of the main wiring pattern 20 in which the resistor element 12, the three-terminal capacitor element 13 and a part 20c of the main wiring pattern are included, constitutes a main current path part, and the sub wiring pattern 21 constitutes a sub current path part. The one end side of the main wiring pattern 20 is electrically connected to a power terminal of the electronic component 10, and the other end side of the main wiring pattern 20 is electrically connected to a positive electrode of the power element 11. The sub wiring pattern 21 is configured to branch from the first branching portion 20a of the main wiring pattern 20 and to connect again to the main wiring pattern 20 at the second branching portion 20b thereof.

Note that, in this embodiment, the power element 11 is implemented on the printed-circuit board 1; however, no limitation is intended by this explanation. Instead of the power element 11, an external power element may be employed.

Further, the resistor element 12 has electrode terminals at both ends in its longitudinal direction, namely in the direction along the main wiring pattern 20. The three-terminal capacitor element 13 has electrode terminals at both ends in its longitudinal direction, the electrodes at both ends being electrically connected to each other, and has a ground terminal between the electrodes at the both ends. These resistor element 12 and three-terminal capacitor element 13 are implemented on the surface of the printed-circuit board 1 so that they are placed in the first wiring layer 2. The resistor element 12 and the three-terminal capacitor element 13 are connected serially through the part 20c of the main wiring pattern placed between the first branching portion 20a and the second branching portion 20b. With respect to the order of connection, the resistor element 12 is provided firstly, and the three-terminal capacitor element 13 is provided secondly, when viewed from the first branching portion 20a. One of the two electrode terminals of the resistor element 12 is connected to the first branching portion 20a side of the main wiring pattern 20, and the other of them is connected to the part 20c side of the main wiring pattern. Further, one of the electrode terminals at the both ends of the three-terminal capacitor element 13 is connected to the part 20c side of the main wiring pattern, and the other of them is connected to the second branching portion 20b side. The ground terminal of the three-terminal capacitor element 13 is connected to the ground conductor 22. The ground conductor 22 is grounded electrically.

It is noted that, in this embodiment, although a surface-mount chip resistor is used as the resistor element 12, no limitation is intended by this explanation. Instead of the chip resistor, a leaded resistor may be used. Likewise, although a stacked type chip capacitor is used as the three-terminal capacitor element 13, no limitation is intended by this explanation. Instead of the chip capacitor, an electrolytic capacitor or a film capacitor may be used. This explanation can also be applied to the resistor element 12 and the three-terminal capacitor element 13 used in Embodiment 2 to be described later.

The above-described noise filter 100 functions as a noise filter when high-frequency electromagnetic noise is generated in the electronic component 10, and can cause the noise current inputted into the main wiring pattern 20 to flow to the ground conductor 22 through the three-terminal capacitor element 13. The noise filter 100 also has a function to stabilize the power supply voltage by removing the noise current.

As shown in FIG. 2, in the main wiring pattern 20 being a main current path, the resistor element 12 and the three-terminal capacitor element 13 are connected serially, and the sub wiring pattern 21 as the sub current path is formed so that its path length is larger than a path length between the first branching portion 20a and the second branching portion 20b in the main wiring pattern 20. This makes it possible to separate noise current in accordance with the noise frequency.

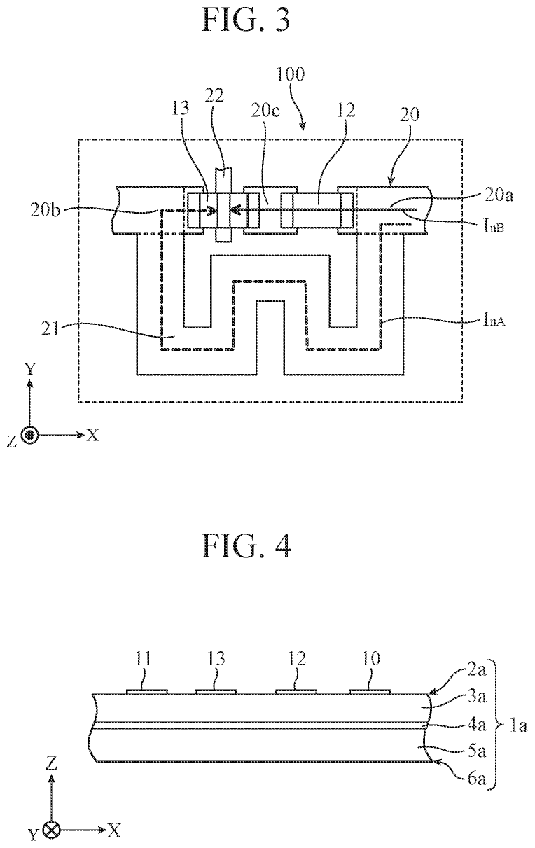

FIG. 3 is a top view of the noise filter 100 for illustrating the mechanism of the noise reduction effect in Embodiment 1.

When noise current flows in from one end of the main wiring pattern 20 being the main current path, the noise current is distributed separately to the current path of the main wiring pattern 20 and the sub wiring pattern 21 dependently on its frequencies. This is because the sub current path composed of the sub wiring pattern 21 is longer than the main current path from the first branching portion 20a to the second branching portion 20b in the main wiring pattern 20. The impedance of the main current path between the first branching portion 20a and the second branching portion 20b is determined by the sum of an inductance depending on the length of that current path and the resistance value of the resistor element 12. The impedance due to the inductance has a proportional relationship with the frequency, whereas the resistance value of the resistor element 12 is almost constant regardless of the frequency. In addition, the impedance of the sub current path due to the sub wiring pattern 21 is determined similarly by the inductance depending on the length of that current path.

Thus, at a frequency which does not exceeds the frequency at which anti-resonance appears, the resistor element 12 has a significant influence, so that the impedance of the sub current path becomes lower than the impedance of the main current path between the first branching portion 20a and the second branching portion 20b. Thus, as shown by a broken line in FIG. 3, the component I_{nA} of the noise current with frequencies which does not exceed the frequency at which anti-resonance appears, flows in the sub current path to reach the second branching portion 20b in the main current path, so that the current is bypassed via the three-terminal capacitor element 13.

In contrast, at a frequency which exceeds the frequency at which anti-resonance appears, an inductance depending on the length of a current path has a significant influence, so that the impedance of the sub current path formed by the sub wiring pattern 21 becomes larger than the impedance of the main current path between the first branching portion 20a and the second branching portion 20b. Thus, as shown by an actual line in the figure, the component I_{nB} of the noise current with frequencies which exceeds the frequency at which anti-resonance appears, is bypassed via the resistor element 12 and the three-terminal capacitor element 13.

As described above, according to Embodiment 1, the resistor element 12 and the three-terminal capacitor element 13 are connected serially between the first branching portion 20a and the second branching portion 20b of the main wiring pattern 20, and the sub wiring pattern 21 being the sub current path is formed so that its path length is larger than the length of the path from the first branching portion 20a to the second branching portion 20b in the main current path, so that only the component I_{nB} of the noise current in the frequency range where anti-resonance occurs can be consumed by the resistor element 12. As a result, it is possible to implement a noise filter and a printed-circuit board which can prevent, while improving the performance of the noise filter in the frequency range where anti-resonance occurs, the performance of the noise filter from deteriorating in the other frequency range.

Further, even when the power terminals of the three-terminal capacitor element 13 implemented serially in the main current path fall into an insulated state therebetween, it is possible to feed power from the power element 11 to the electronic component 10 through the sub current path formed by the sub wiring pattern 21. On the other hand, when the power terminals are not in the insulated state therebetween, as described above, a high frequency component of noise current is bypassed via the resistor element 12 and the three-terminal capacitor element 13 that are connected in the main path. Thus, it is possible to suppress the high frequency component of noise current flowing out from the circuit element to a power feeding point without passing the three-terminal capacitor element 13.

Therefore, it is possible to provide a noise filter which prevents, while improving the performance of the noise filter in the frequency range where anti-resonance occurs, the performance of the noise filter from deteriorating in the other frequency range, and which increases the product durability without deterioration in the performance.

It is noted that the printed-circuit board 1 in this embodiment is a single-sided printed mounting board and thus the first wiring layer 2 is configured as an outer layer of a double-sided printed mounting board; however, no limitation is intended by this explanation. For example, the first wiring layer 2 may be configured as an inner layer in a multi-layer printed-circuit board including three or more wiring layers. Here, the outer layer means an outermost wiring layer among multiple wiring layers of the printed-circuit board, and the inner layer means an inside wiring layer among multiple wiring layers of the printed-circuit board.

Further, although the main wiring pattern 20 is formed to be a linear shape, the shape is not limited thereto. Further, although the sub wiring pattern 21 is formed to be a meandering shape, the shape is not limited thereto.

As described above, the noise filter according to Embodiment 1 includes: a main current path part arranged between a power element and a circuit element; a sub current path part that braches from a first branching point placed at one end of the main current path part and that connects to the main current path part at a second branching point placed at another end of the main current path part; a three-terminal capacitor element having a pair of electrode terminals and a ground terminal arranged between the pair of electrode terminals, in which the pair of electrode terminals are connected serially in a path from the first branching point to the second branching point, and the ground terminal is connected to a ground conductor; and a resistor element having a pair of electrode terminals which are connected serially in the path from the first branching point to the second branching point. A path length of the sub current path part is larger than a length of the path from the first branching point to the second branching point in the main current path part. Thus, it is possible, while reducing noise current in the frequency range where anti-resonance occurs, to prevent the performance from deteriorating in the other frequency range, and to increase the durability.

Further, according to the noise filter of Embodiment 1, the main current path part, the sub current path part, the three-terminal capacitor element, the ground conductor and the resistor element are implemented in a same wiring layer of a printed-circuit board. The main current path part is formed as a main wiring pattern in the same wiring layer and the sub current path part is formed as a sub wiring pattern in the same wiring layer. The three-terminal capacitor element and the resistor element are connected serially in the main wiring pattern. Thus, it is possible to provide a noise filter for the printed-circuit board, which can prevent, while reducing noise current in the frequency range where anti-resonance occurs, the performance from deteriorating in the other frequency range, and which can increase the durability.

### Embodiment 2

In a noise filter of Embodiment 2, the noise filter of the present invention is extended to a case using a multi-layer board in which the area for implementing the noise filter is reduced by forming a filter structure in multiple layers.

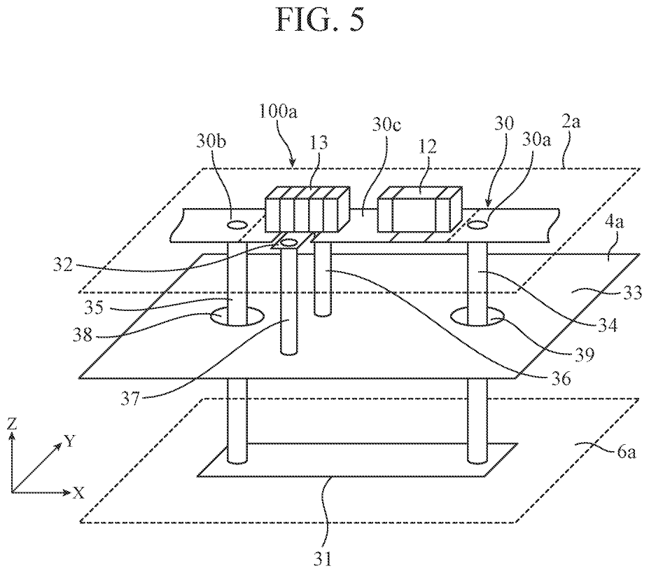

FIG. 4 is an illustration diagram of a layered structure of a printed-circuit board 1a for implementing the noise filter according to Embodiment 2 of the invention. The illustrated printed-circuit board 1a is a three-layer printed-circuit board having a layered structure in which, in a thickness direction Z, a first wiring layer 2a and a second wiring layer 4a are stacked via an insulating layer 3a and further the second wiring layer 4a and a third wiring layer 6a are stacked via an insulating layer 5a. Each of the first wiring layer 2a, the second wiring layer 4a, and the third wiring layer 6a is distributed in an X-Y plane perpendicular to the thickness direction Z. On the first wiring layer 2a at the surface of the printed-circuit board 1a, an electronic component 10 such as an LSI or IC, a power element 11, a resistor element 12 and a three-terminal capacitor element 13 are implemented. The insulating layer 3a is formed by electrical insulation resin material such as, for example, an epoxy resin, a polyimide resin or the like. Further, though not illustrated in FIG. 4, an interlayer connection hole that is referred to as a via or through-hole is formed to pass through the insulating layer 3a and the insulating layer 5a in the thickness direction Z to thereby make electrical connection between the first wiring layer 2a and the second wiring layer 4a, or the first wiring layer 2a and the third wiring layer 6a (see, FIG. 5 described below).

FIG. 5 is a perspective view showing a configuration of a noise filter 100a of Embodiment 2. The illustrated noise filter 100a includes: a main wiring pattern 30; a sub wiring pattern 31; a ground connection wiring 32; a resistor element 12; and a three-terminal capacitor element 13.

The main wiring pattern 30 and the ground connection wiring 32 are formed on a surface layer of the insulating layer 3 as a group of configuration elements of the first wiring layer 2a. Further, the sub wiring pattern 31 is formed on a surface layer of the insulating layer 5a as a group of configuration elements of the third wiring layer 6a. Further, the first wiring layer 2a and the third wiring layer 6a are each formed by an electrical conductor such as a copper foil or the like. Further, the noise filter 100a includes a ground conductor 33 that is grounded electrically as a configuration element of the second wiring layer 4a. The ground conductor 33 is formed by electrically conductive material such as a copper foil or the like, and is formed to be a sheet shape. Furthermore, the noise filter 100a includes: a first interlayer connection hole 34 and a second interlayer connection hole 35 each passing through the insulating layer 3a and the insulating layer 5a in the thickness direction Z; and a third interlayer connection hole 36 and a fourth interlayer connection hole 37 each passing through the insulating layer 3a in the thickness direction Z. On the inside of each of these first interlayer connection hole 34, second interlayer connection hole 35, third interlayer connection hole 36 and fourth interlayer connection hole 37, a connection conductor such as an electrically conductive paste, a metal plating layer or the like, is formed. Namely, in each of the first interlayer connection hole 34 and the second interlayer connection hole 35, a pattern connection conductor is formed, and in each of the second interlayer connection hole 35 and the third interlayer connection hole 36, a ground connection conductor is formed. Thus, in the first wiring layer 2a, a first branching portion 30a placed on one end side of the main wiring pattern 30 and the pattern connection conductor in the first interlayer connection hole 34 are electrically connected to each other, and a second branching portion 30b placed on another end side of the main wiring pattern 30 and the pattern connection conductor in the second interlayer connection hole 35 are electrically connected to each other. Further, the ground connection wiring 32 and the ground connection conductors in the third interlayer connection hole 36 and the fourth interlayer connection hole 37 are electrically connected to each other.

In the second wiring layer 4a, the ground conductor 33 and the ground connection conductors in the third interlayer connection hole 36 and the fourth interlayer connection hole 37 are electrically connected to each other. Further, in the second wiring layer 4a, a first clearance 38 is formed around the first interlayer connection hole 34 and a second clearance 39 is formed around the second interlayer connection hole 35. Thus, the first interlayer connection hole 34 and the second interlayer connection hole 35 are electrically insulated from the ground conductor 33. In the third wiring layer 6a, one end portion of the sub wiring pattern 31 and the first interlayer connection hole 34 are electrically connected to each other, and another end portion of the sub wiring pattern 31 and the second interlayer connection hole 35 are electrically connected to each other. The side of the main wiring pattern 30 where the first branching portion 30a is placed is electrically connected to a power terminal of the electronic component 10, and the side of the main wiring pattern 30 where the second branching portion 30b is placed is electrically connected to a positive electrode of the power element 11.

Note that, in this embodiment, the power element 11 is implemented on the printed-circuit board 1; however, no limitation is intended by this example. Instead of the power element 11, an external power element may be employed.

Further, the noise filter 100a is provided with the resistor element 12 and the three-terminal capacitor element 13 as shown in FIG. 5. These resistor element 12 and three-terminal capacitor element 13 are implemented on a surface of the printed-circuit board 1a to be placed in the first wiring layer 2a. The resistor element 12 and the three-terminal capacitor element 13 are connected serially between the first branching portion 30a and the second branching portion 30b of the main wiring pattern 30 via a part 30c of the main wiring pattern 30. With respect to the order of connection, the resistor element 12 is provided firstly, and the three-terminal capacitor element 13 are provided secondly, when viewed from the first branching portion 30a. One of the electrode terminals of the resistor element 12 is connected to the first branching portion 30a side of the main wiring pattern 30, and the other electrode terminal thereof is connected to the part 30c of the main wiring pattern. One of the electrode terminals of the three-terminal capacitor element 13 is connected to the part 30c of the main wiring pattern and the other electrode terminal thereof is connected to the second branching portion 30b, and the ground terminal thereof is connected to the ground connection wiring 32.

The noise filter 100a functions as a noise filter when high-frequency electromagnetic noise is generated in the electronic component 10, and can cause the noise current inputted into the main wiring pattern to flow to the ground conductor 33 through the three-terminal capacitor element 13. The noise filter 100a also has a function to stabilize the power supply voltage by removing the noise current.

As shown in FIG. 5, between the first branching portion 30a and the second branching portion 30b of the main wiring pattern 30, the resistor element 12 and the three-terminal capacitor element 13 are connected serially, and the sub current path, formed by the sub wiring pattern 31 and the pattern connection conductors in the first interlayer connection hole 34 and the second interlayer connection hole 35, is formed so that its path length is larger than a path length of a main current path between the first branching portion 30a and the second branching portion 30b. Consequently, also in this embodiment, it is possible to achieve the noise reduction effect due to the same mechanism as shown in Embodiment 1. Further, according to Embodiment 2, since the pattern connection conductors in the first interlayer connection hole 34 and the second interlayer connection hole 35 are included in the sub current path, it is possible to implement a noise filter using the printed-circuit board 1a that is smaller in area than that in Embodiment 1.

It is noted that the printed-circuit board 1a in this embodiment is a three-layer printed mounting board and thus the first wiring layer 2a is formed as an outer layer of a double-sided printed mounting board; however, no limitation is intended by this example. For example, the first wiring layer 2a may be configured as an inner layer in a multi-layer printed-circuit board including four or more wiring layers. Here, the outer layer means an outermost wiring layer of the multiple wiring layers of the printed-circuit board, and the inner layer means an inside wiring layer of the multiple wiring layers of the printed-circuit board.

Further, although the main wiring pattern 30, the sub wiring pattern 31 and the ground connection wiring 32 are each formed to be a linear shape, the shape is not limited thereto. Furthermore, although two connection holes, that is, the first interlayer connection hole 34 and the second interlayer connection hole 35 passing through the insulating layer 3a in the thickness direction Z are used in the sub current path, the number thereof is not limited thereto. Likewise, although two holes, that is, the third interlayer connection hole 36 and the fourth interlayer connection hole 37 are connected to the ground connection wiring 32, the number thereof is not limited thereto.

Further, although the ground conductor 33 is provided in the second wiring layer 4a, it may be provided in the first wiring layer 2a similarly to Embodiment 1.

Furthermore, although the first interlayer connection hole 34, the second interlayer connection hole 35, the third interlayer connection hole 36 and the fourth interlayer connection hole 37 have each a cylindrical column shape, their shapes are not limited thereto. Instead of that cylindrical column shape, a polygonal column shape may be employed.

As described above, according to the noise filter of Embodiment 2, the main current path part, the three-terminal capacitor element, the ground conductor and the resistor element, are implemented in the first wiring layer of the printed-circuit board having multiple wiring layers; the main current path part is formed as the main wiring pattern in the first wiring layer, and the sub current path part is formed of the sub wiring pattern formed in a wiring layer different to the first wiring layer and the pattern connection conductor that connects the main wiring pattern with the sub wiring pattern; and the three-terminal capacitor element and the resistor element are connected serially in the main wiring pattern. Thus, in addition to providing the effect in Embodiment 1, it is possible to reduce the area of a printed-circuit board for implementing a noise filter.

Further, according to the noise filter of Embodiment 2, the main current path part, the three-terminal capacitor element, the ground conductor and the resistor element are implemented in a first wiring layer of a printed-circuit board having multiple wiring layers. The main current path part is formed as a main wiring pattern in the first wiring layer, and the sub current path part is formed of a sub wiring pattern formed in a wiring layer different to the first wiring layer and a pattern connection conductor that connects the main wiring pattern with the sub wiring pattern. The three-terminal capacitor element and the resistor element are connected serially in the main wiring pattern. Thus, it is possible to further reduce the implementation area.

In the above, various embodiments according to the present invention have been described with reference to the drawings; however, these embodiments are merely examples of the invention, and various embodiments other than the above may also be employed. For example, with respect to each of the noise filters 100, 100a of the above embodiments, its number is not limited to one, and a multiple number of such filters may be implemented. Further, a filter array which is configured with a multiple number of the noise filers 100 or 100a according to the above embodiments that are connected in a cascade manner may be implemented on a single printed-circuit board. Further, any side of each of the noise filter 100 or 100a may by used as an input side or an output side.

Further, the basic configuration of the noise filters 100, 100a of Embodiments 1, 2 can be applied, not only to a printed-circuit board, but also to a circuit having a layered structure, such as a semiconductor integrated circuit or the like.

It should be noted that any combination of Embodiments 1, 2, modification of any configuration element in the respective embodiments and omission of any configuration element in the respective embodiments can be made in the present invention without departing from the scope of the invention.

### INDUSTRIAL APPLICABILITY

As described above, the noise filter according to the invention is related to a configuration for removing high-frequency electromagnetic noise that will leak due to anti-resonance caused by a parasitic component in a printed-circuit board, and is suitable for use in a printed-circuit board on which various circuit elements are implemented.

### DESCRIPTION OF REFERENCE NUMERALS AND SIGNS

1, 1a: printed-circuit board, 2, 2a: first wiring layer, 3, 3a, 5a: insulating layer, 4a: second wiring layer, 6a: third wiring layer, 10: electronic component, 11: power element, 12: resistor element, 13: three-terminal capacitor element, 20, 30: main wiring pattern, 20a, 30a: first branching portion, 20b, 30b: second branching portion, 21, 31: sub wiring pattern, 22, 33: ground conductor, 32: ground connection wiring, 34: first interlayer connection hole, 35: second interlayer connection hole, 36: third interlayer connection hole, 37: fourth interlayer connection hole, 38: first clearance, 39: second clearance, 100, 100a: noise filter.

1. A noise filter comprising:
a main current path part arranged between a power element and a circuit element;
a sub current path part that braches from a first branching point placed at one end of the main current-path part and that connects to the main current-path part at a second branching point placed at another end of the main current-path part;
a three-terminal capacitor element having a pair of electrode terminals and a ground terminal arranged between the pair of electrode terminals, in which the pair of electrode terminals are connected serially in a path from the first branching point to the second branching point, and the ground terminal is connected to a ground conductor; and
a resistor element having a pair of electrode terminals which are connected serially in the path from the first branching point to the second branching point,
wherein the three-terminal capacitor element and the resistor element are serially connected to each other, and
wherein a path length of the sub current path part is larger than a length of the path from the first branching point to the second branching point in the main current path part so that an impedance of the sub current path part is larger than an impedance of the path from the first branching point to the second branching point in a frequency range which exceeds a frequency at which anti-resonance caused by noise current appears.

2. The noise filter of claim 1, wherein the main current path part, the sub current path part, the three-terminal capacitor element, the ground conductor and the resistor element are implemented in a same wiring layer of a printed-circuit board,
wherein the main current path part is formed as a main wiring pattern in the same wiring layer and the sub current path part is formed as a sub wiring pattern in the same wiring layer, and
wherein the three-terminal capacitor element and the resistor element are connected serially in the main wiring pattern.

3. The noise filter of claim 1, wherein the main current path part, the three-terminal capacitor element, the ground conductor and the resistor element are implemented in a first wiring layer of a printed-circuit board having multiple wiring layers,
wherein the main current path part is formed as a main wiring pattern in the first wiring layer, and the sub current path part is formed of a sub wiring pattern formed in a wiring layer different to the first wiring layer and a pattern connection conductor that connects the main wiring pattern with the sub wiring pattern, and
wherein the three-terminal capacitor element and the resistor element are connected serially in the main wiring pattern.

4. The noise filter of claim 1, wherein the main current path part, the three-terminal capacitor element and the resistor element are implemented in a first wiring layer of a printed-circuit board having three or more wiring layers,
wherein the main current path part is formed as a main wiring pattern in the first wiring layer, and the sub current path part is formed of a sub wiring pattern formed in a third wiring layer of the printed-circuit board and a pattern connection conductor that connects the main wiring pattern with the sub wiring pattern, and the ground conductor is formed in a second wiring layer of the printed-circuit board, the ground conductor and the ground terminal being connected to each other by a ground connection conductor, and
wherein the three-terminal capacitor element and the resistor element are connected serially in the main wiring pattern.
